(19) United States
(12) Patent Application Publication
(10) Pub. No.: US 2013/0163168 A1
(43) Pub. Date: Jun. 27, 2013

(54) SERVER CABINET

(71) Applicant: An-Gang LIANG, Shenzhen City (CN)

(72) Inventor: An-Gang LIANG, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 13/474,725

(22) Filed: May 18, 2012

(30) Foreign Application Priority Data
Dec. 22, 2011 (CN) 201110435089.0

(51) Int. Cl. H05K 7/00; H05K 5/03; H05K 5/02

(52) U.S. Cl. 361/679.02; 312/223.2

(57) ABSTRACT

A server cabinet includes a housing and a cable management bracket. The cable management bracket includes a base plate fastened to the housing and two side plates extending from opposite sides of the base plate. Each side plate defines a number of openings for cables to extend through.

### CROSS-REFERENCE TO RELATED APPLICATION

Relevant subject matter is disclosed in a pending U.S. patent application, titled “SERVER CABINET”, filed on May 16, 2012, with the application Ser. No. 13/472,512, which is assigned to the same assignee as this patent application.

### BACKGROUND

1. Technical Field

The present disclosure relates to a server cabinet.

2. Description of Related Art

Switches are generally mounted on a top of a server cabinet; and a plurality of servers is mounted in the cabinet, below the switches. A plurality of cables is provided for connecting the switches and servers. However, due to the large number of cables, it is often difficult to manage the cables in a neat way.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled view of an exemplary embodiment of a server cabinet.

FIG. 2 is similar to FIG. 1, but viewed from a different perspective.

FIG. 3 is a partially exploded, isometric view of the cabinet of FIG. 2, wherein the cabinet includes two latching members and a plurality of covers.

FIG. 4 is an enlarged view of a circled portion IV of FIG. 3.

FIG. 5 is an enlarged view of one of the latching members of FIG. 3.

FIG. 6 is an enlarged view of one of the covers of FIG. 3, but viewed from a different perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

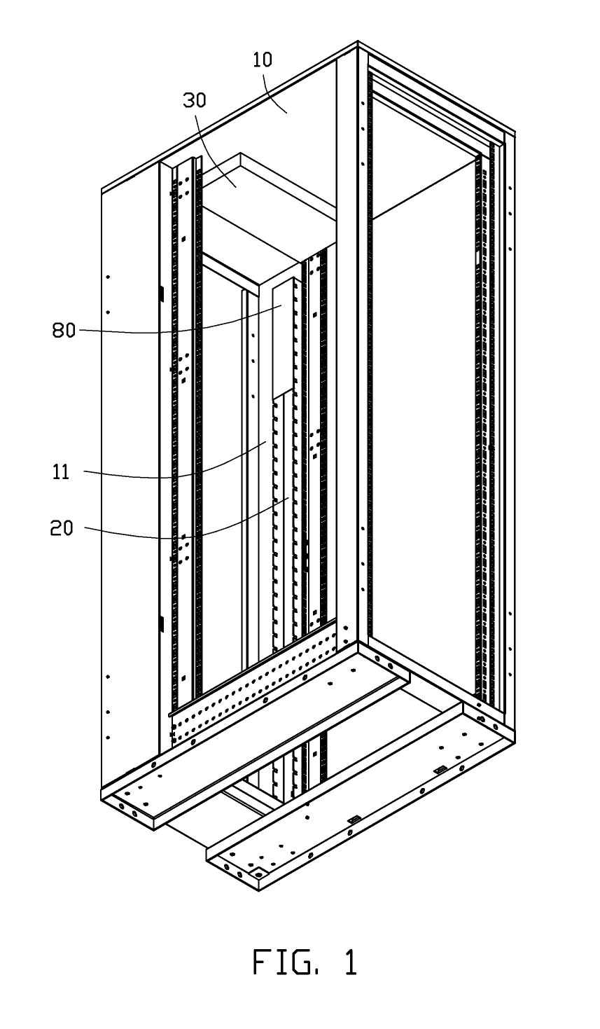

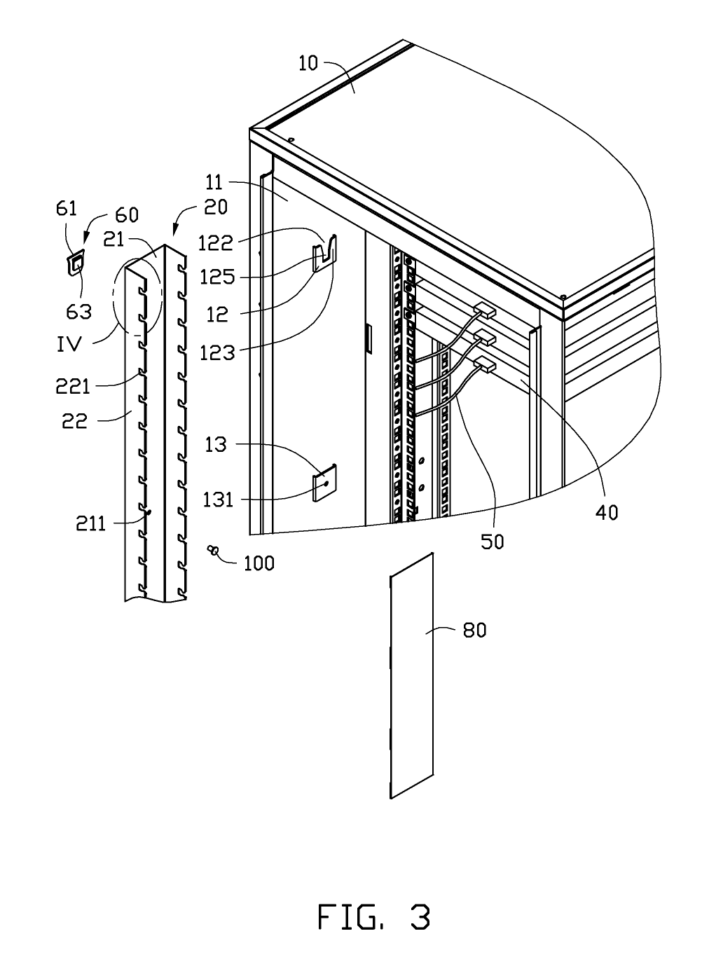

FIGS. 1 and 3 show an exemplary embodiment of a server cabinet including a housing 10, a cable management bracket 20, two latching members 60, and a plurality of covers 80.

A switch 30 is mounted on an inner surface of a top of the housing 10. A plurality of servers 40 is mounted in the housing 10 from top to bottom, below the switch 30. The housing 10 includes a side plate 11 to enclose the servers 40. Two engaging portions 12 are respectively formed on an upper portion and a lower portion of an inner surface of the side plate 11, behind the switch 30 and the servers 40. Each engaging portion 12 is substantially U-shaped in cross-section, including a sidewall 123 parallel to the side plate 11. An inlet 122 is defined in a top of each engaging portion 12. A notch 125 is defined in each sidewall 123, extending through a top of each sidewall 123. A U-shaped cross section locking portion 13 is formed on a middle of the side plate 11. A locking hole 131 is defined in a middle of the locking portion 13.

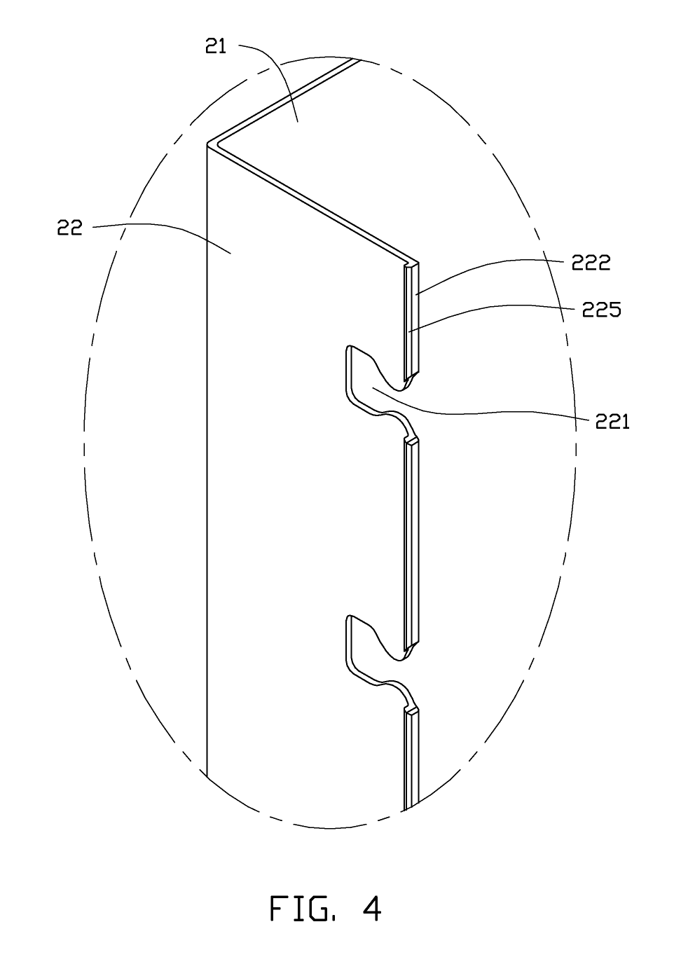

FIGS. 3 and 4 show each cable management bracket 20 including an elongated base plate 21, and two side plates 22 perpendicularly extending from opposite sides of the base plate 21. A through hole 211 is defined in a middle of the base plate 21. A plurality of spaced openings 221 is defined in each side plate 22, arranged along a lengthwise direction of the side plate 22 and extending through a first side of the side plate 22 away from the base plate 21. A plurality of spaced bars 222 perpendicularly extends out from the first side of each side plate 22, away from the other side plate 22. Each opening 221 is located between two corresponding neighboring bars 222. A slanting guiding surface 225 is formed on a distal side of each bar 222, opposite to the corresponding side plate 22. The distance between every two neighboring openings 221 of each side plate 22 is approximately the same as the height of the server 40.

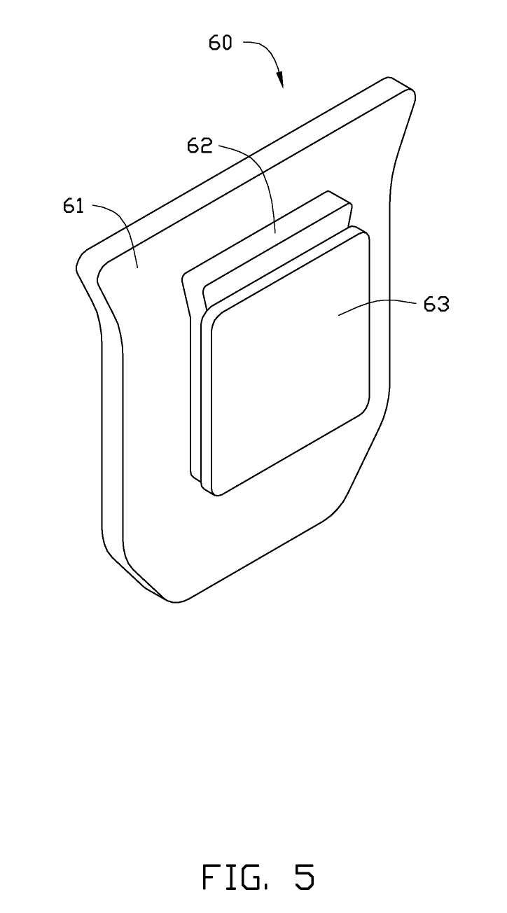

FIG. 5 shows each latching member 60 including a main body 61, a connection block 62 formed on a side of the main body 61, and a fastening portion 63 formed on a side of the connection block 62 away from the main body 61.

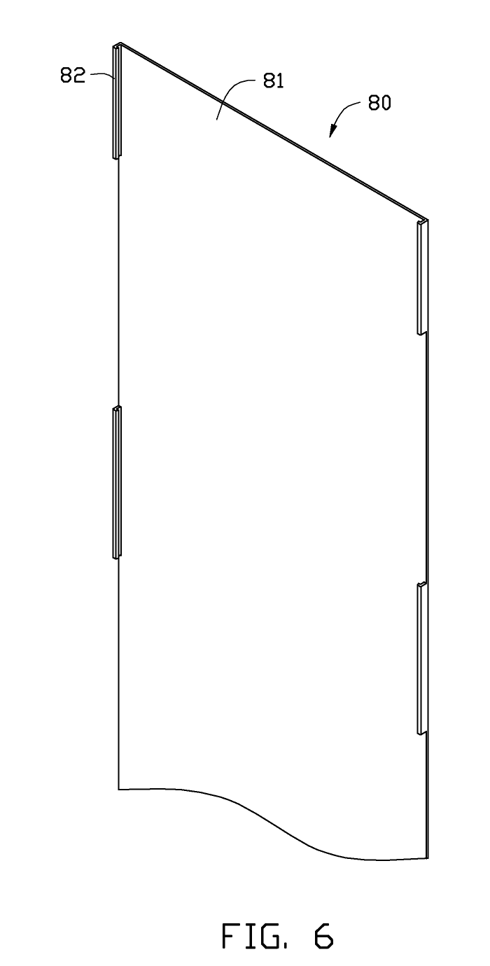

FIG. 6 shows each cover 80 including an elongated covering plate 81 and two rows of spaced hooks 82 extending from opposite sides of the covering plate 81. Each hook 82 is substantially L-shaped, perpendicularly extending from the corresponding side of the covering plate 81 and then extending toward the opposite side of the covering plate 81.

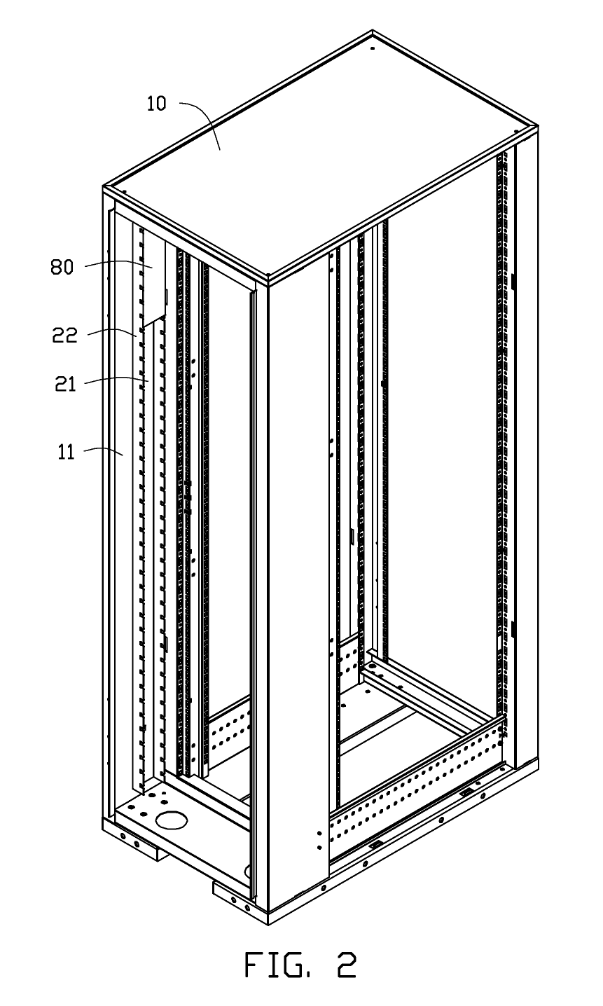

FIGS. 2 and 3 show in assembly, the fastening portions 63 are respectively welded to an upper portion and a lower portion of an outer side surface of the base plate 21 opposite to the side plates 22. The main bodies 61 engage in the corresponding engaging portions 12 through the inlets 122. The connection blocks 62 engage in the corresponding notches 125. A fastener 100, such as a screw, extends through the through hole 211, and then engages in the locking hole 131. Each server 40 corresponds to two corresponding openings 221 of the side plates 22 of the cable management bracket 20. A cable 50 connected to a rear side of the server 40 extends through one of the two corresponding openings 221 of the side plates 22, and extends up along the side plate 22 opposite to the server 40 to be connected to a rear side of the switch 30. One of the covers 80 is pressed toward the cable management bracket 20. The hooks 82 of the cover 80 engage with the corresponding bars 222, due to guiding of the guiding surfaces 225 and the resilience of the hooks 82. Therefore, the cover 80 is mounted to the cable management bracket 20, preventing the cables 50 from disengaging from the cable management bracket 20. Other covers 80 are mounted to the cable management bracket 20 from top to bottom, using the same manner as described above.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A server cabinet, comprising:
a housing; and
a cable management bracket comprising a base plate fastened to the housing, and two first side plates extending from opposite sides of the base plate, each first side plate defining a plurality of openings for cables to extend through.

2. The server cabinet of claim 1, wherein the housing comprises a second side plate, an engaging portion is formed on the second side plate, a latching member is fastened to an outer side surface of the base plate opposite to the first side plates to engage in the engaging portion.

3. The server cabinet of claim 2, wherein the engaging portion is substantially U-shaped in cross-section, comprising a sidewall parallel to the second side plate, an inlet is defined in a top of the engaging portion, the latching member comprises a main body for engaging in the engaging portion through the inlet and a fastening portion fastened to the base plate.

4. The server cabinet of claim 3, wherein a notch is defined in the sidewall, extending through a top of the sidewall, the latching member further comprises a connection block for engaging in the notch, the connection block is connected between the main body and the fastening portion.

5. The server cabinet of claim 4, wherein the fastening portion is welded to the base plate.

6. The server cabinet of claim 2, wherein a locking portion is formed on the second side plate, a locking hole is defined in the locking portion, the base plate defines a through hole, a fastener extends through the through hole and engages in the locking hole.

7. The server cabinet of claim 6, wherein the locking portion is U-shaped in cross section.

8. The server cabinet of claim 1, further comprising a cover detachably mounted to first sides of the first side plates opposite to the base plate.

9. The server cabinet of claim 8, wherein a plurality of bars perpendicularly extends from the first side of each first side plate, away from the other first side plate, the cover comprises a covering plate opposite to the base plate for covering the cable management bracket, and a plurality of hooks extending from opposite sides of the covering plate, to engage with the bars.

10. The server cabinet of claim 9, wherein a slanting guiding surface is formed on a distal side of each bar.

11. The server cabinet of claim 1, further comprising a plurality of servers, wherein a switch is mounted on a top of the housing, the servers are mounted in the housing, below the switch, the servers are connected to the switch through the cables.

12. The server cabinet of claim 11, wherein a distance between two neighboring ones of the openings of each first side plate is the same as a height of one of the servers.
